(19) United States
(12) Patent Application Publication
(10) Pub. No.: US 2016/0377878 A1
(43) Pub. Date: Dec. 29, 2016

(54) COMPOSITE LASER LINE PROJECTOR TO REDUCE SPECKLE

(71) Applicant: OSELA INC., Montreal (CA)

(72) Inventor: Francis Cayer, Saint-Eustache (CA)

(21) Appl. No.: 15/188,129

(22) Filed: Jun. 21, 2016

Related U.S. Application Data
(60) Provisional application No. 62/184,941, filed on Jun. 26, 2015.

(51) Int. Cl. G02B 27/48; G02B 27/10; G02B 27/09; H01S 5/40; G02B 27/12; G02B 19/00; H01S 5/42

(52) U.S. Cl. CPC G02B 27/48; G02B 19/0009; G02B 19/0057; G02B 27/1006; H01S 5/423; H01S 5/4087; G02B 27/12; G02B 27/0905

(57) ABSTRACT

To reduce speckle, a composite laser line beam is formed by the superposition of coherent laser line beams projected at different angles towards a target during use. The superposition of the coherent laser line beams combined with their differing angles of incidence relative to the target allow the composite laser line beam to have a reduced amount of speckles, which is desirable when illuminating the target in imaging applications. The laser line projector generally has a frame, a projection plane, laser sources and a reformatting assembly. During use, the laser sources project coherent laser beams towards the reformatting assembly which reformats the coherent laser beams into the coherent laser line beams to form the composite laser line beam.

### FIELD

The improvements generally relate to the field of illuminating objects with light beams and more particularly relate to the field of illuminating objects with laser line beams.

### BACKGROUND

Line beam projectors are used in various applications to project a line of light on a surface.

A technology which is commonly used for line projection is based on light-emitting diodes (LEDs). This technology can produce a relatively high quality of light at close-range. Moreover, the light generated by a LED is incoherent, so no speckle is produced when illuminating the surface with the line beam. However, the light produced by the LED typically diffuses and thus diverges over distance, making it misadapted to the production of a narrow line beam especially over greater distances.

Another technology which has been used for line projection is laser-based. The coherent light produced by a laser source can be much better suited to produce narrower lines of light over relatively long distances. However, since coherent light is produced by the laser source, this technology is prone to produce speckle when projected on an imperfect surface. This phenomenon can be undesirable in applications where uniformity is important, such as imaging applications for instance.

Accordingly, although line beam projectors were satisfactory to a certain degree, there remains room for improvement in alleviating the drawbacks of either one of these two technologies.

### SUMMARY

There is provided a laser line projector which has the advantages of the laser-based technology, but where the speckle significantly reduced. More specifically, the reduction of the speckle is achieved by producing a composite laser line beam.

In accordance with one aspect, there is provided a laser line projector for projecting a composite laser line beam on a target, the laser line projector comprising: a frame; a projection plane at a given position relative to the frame; a plurality of laser sources, being incoherent to one another, secured to the frame, spaced from one another and having a corresponding plurality of laser beam paths; and a reformatting assembly secured to the frame receiving the plurality of laser beam paths, the reformatting assembly reformatting each of the laser beam paths into one of a plurality of laser line beam paths aligned with the projection plane, the plurality of laser sources and the reformatting assembly being arranged relative to one another such that the plurality of laser line beam paths are projected at different angles towards the target and superposed with one another to form the composite laser line beam during use.

In accordance with another aspect, there is provided a method for projecting a composite laser line beam on a target, the method comprising the steps of: providing a plurality of laser beams being incoherent with one another; reformatting each of the laser beams into one of a plurality of laser line beams; and projecting, during use, the plurality of laser line beams at different angles towards the target, aligned with a projection plane and superposed with one another to form the composite laser line beam on the target.

In accordance with another aspect, there is provided an imaging system for imaging a composite laser line beam on a target, the system comprising: a laser line projector comprising: a frame; a projection plane at a given position relative to the frame; a plurality of laser sources, being incoherent to one another, secured to the frame, spaced from one another and having a corresponding plurality of laser beam paths; and a reformatting assembly secured to the frame receiving the plurality of laser beam paths, the reformatting assembly reformatting each of the laser beam paths into one of a plurality of laser line beam paths aligned with the projection plane, the plurality of laser sources and the reformatting assembly being arranged relative to one another such that the plurality of laser line beam paths are projected at different angles towards the target and superposed with one another to form the composite laser line beam during use; and an imaging assembly configured to image the composite laser line beam on the target.

Many further features and combinations thereof concerning the present improvements will appear to those skilled in the art following a reading of the instant disclosure.

### DESCRIPTION OF THE FIGURES

In the figures,

FIG. 1 is a schematic, oblique view of an example of an imaging system for imaging a laser line beam on a target, in accordance with an embodiment;

FIG. 2 is a schematic, top view of an example of a laser line projector with a single reformatting assembly, in accordance with an embodiment;

FIG. 3A is a schematic, top view of an example of a laser line projector with two reformatting assemblies including acylindrical lenses, in accordance with an embodiment;

FIG. 3B is a schematic, top view of another example of a laser line projector with two reformatting assemblies including diffusing elements, in accordance with an embodiment;

FIG. 4 is a schematic, top view of an example of a laser line projector with redirecting elements and laser sources aligned along a projection plane, in accordance with an embodiment;

FIG. 5A is a schematic, side view of an example of a laser line projector, with a composite laser line beam formed at a laser line beam junction, in accordance with an embodiment;

FIG. 5B is a cross-sectional view taken along section 5B-5B of FIG. 5A, in accordance with an embodiment;

FIG. 6A is a cross-sectional view taken along a projection plane of an example of a laser line projector with five reformatting assemblies, in accordance with an embodiment;

FIG. 6B is a cross-sectional view taken along section 6B-6B of FIG. 6A showing a window, in accordance with an embodiment;

FIG. 7 is a schematic, top view of an example of a laser line projector with a monolithic optical device, in accordance with an embodiment;

FIG. 8A is a schematic, oblique view of an example of a solid-state monolithic optical device, in accordance with an embodiment; and

FIG. 8B is a schematic, oblique view of an example of a monolithic optical device aligning multiple optical fibers, in accordance with an embodiment.

These figures depict example embodiments for illustrative purposes, and variations, alternative configurations, alternative components and modifications may be made to these example embodiments.

### DETAILED DESCRIPTION

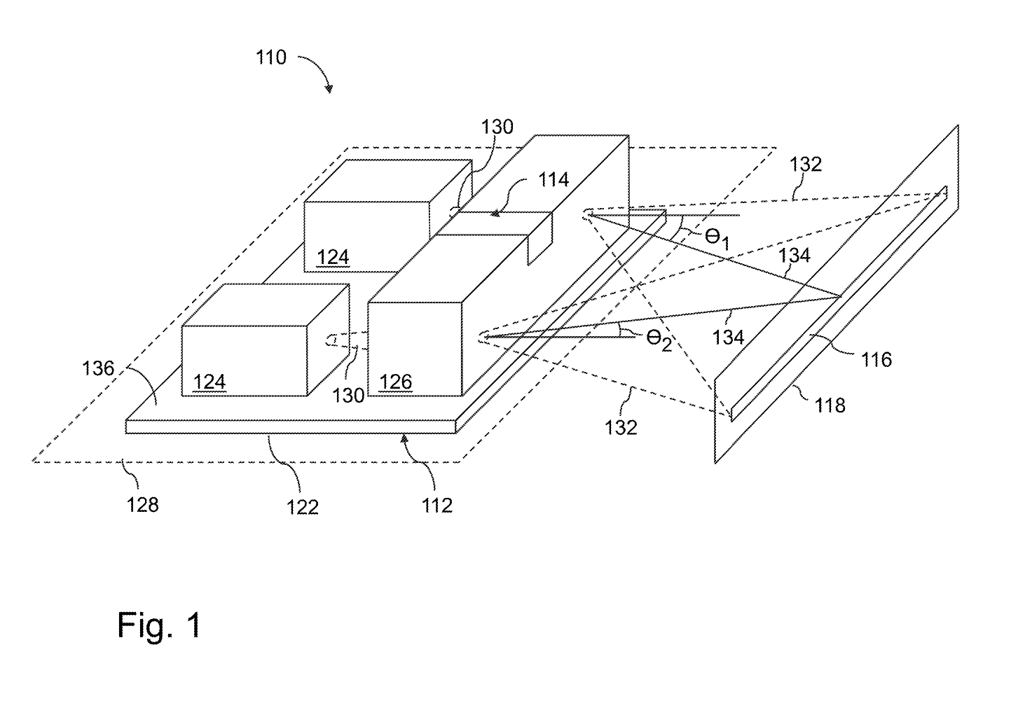

FIG. 1 shows an example of an imaging system 110 comprising a laser line projector 112 and an imaging assembly 114. The laser line projector 112 is used to project a composite laser line beam 116 having a reduced amount of speckles towards a target 118. Broadly stated, the laser line beam 116 is formed by the superposition of a plurality of coherent laser line beams projected at different angles towards the target 118 by the laser line projector 112 during use. The superposition of the coherent laser line beams combined with their differing angles of incidence relative to the target 118 form a composite line which allows for speckle reduction, which is desirable when illuminating the target 118 in imaging applications. Moreover, it is contemplated that the superposition of the coherent laser line beams can help achieve laser line beams having greater power.

As seen in the example shown in FIG. 1, the laser line projector 112, which can reduce speckle, has a frame 122 to which are secured a plurality of laser sources 124 and a reformatting assembly 126. The laser sources 124 can include any suitable type of laser sources such as laser diodes, gas lasers, fiber lasers, vertical external-cavity surface-emitting lasers (VECSELs), VECSELs array and the like. The laser sources 124 are incoherent to one another in the sense that each of the laser sources are configured to emit a laser beam which is coherent in nature, but wherein each of the individual coherent laser beams are incoherent with respect to one another. As will be understood by persons skilled in the art, this incoherence between the laser beams helps avoid speckling which could otherwise stem from interference between the laser line beams. The laser line projector 112 has a projection plane 128 defined therein. Each of the laser sources 124 has a laser beam path 130 which extends from a corresponding one of the laser sources 124 towards the reformatting assembly 126. The laser sources 124 and the reformatting assembly 126 are arranged such that the laser beam paths 130 are received and reformatted into a plurality of laser line beam paths 132 also extending, in a superposed manner, along the projection plane 128. Each of the laser line beam paths 132 has an optical axis 134 associated thereto which is oriented towards the target 118 at different angles θ. As depicted, angle θ₁ is different from angle θ₂ (θ₁≠θ₂). In an embodiment, the speckling reduction is proportional to the inverse of the square root of the number of superposed laser line beam paths 132, the number of laser sources 124 is thus relevant when designing such a laser line projector 112.

During use, the laser sources 124 are activated such that the laser beams are projected, from each one of the laser sources 124, along their corresponding laser beam paths 130. Correspondingly, the laser beams are reformatted into the laser line beams with respect to their corresponding laser line beam paths 132 to form the composite laser line beam 116.

The imaging assembly 114 is used to image the projection of the composite laser line beam 116 on the target 118. In an embodiment, the imaging assembly 114 comprises a coupled-charge device (CCD) and imaging optics (not shown). However, any imaging assembly that may be deemed suitable may be used. FIG. 1 shows that the imaging assembly 114 is secured to the laser line projector 112 however, it is understood that the imaging assembly can be made separate from the laser line projector 112. In other words, the imaging assembly 114 can be provided at a remote location relative to the laser line projector 112. In this example, the projection plane 128 extends parallel with a main surface 136 of the frame 122 and is aligned with both the laser beam paths 130 and the laser line beam paths 132. More specifically, the composite laser line beam 116 coincides with the projection plane 128.

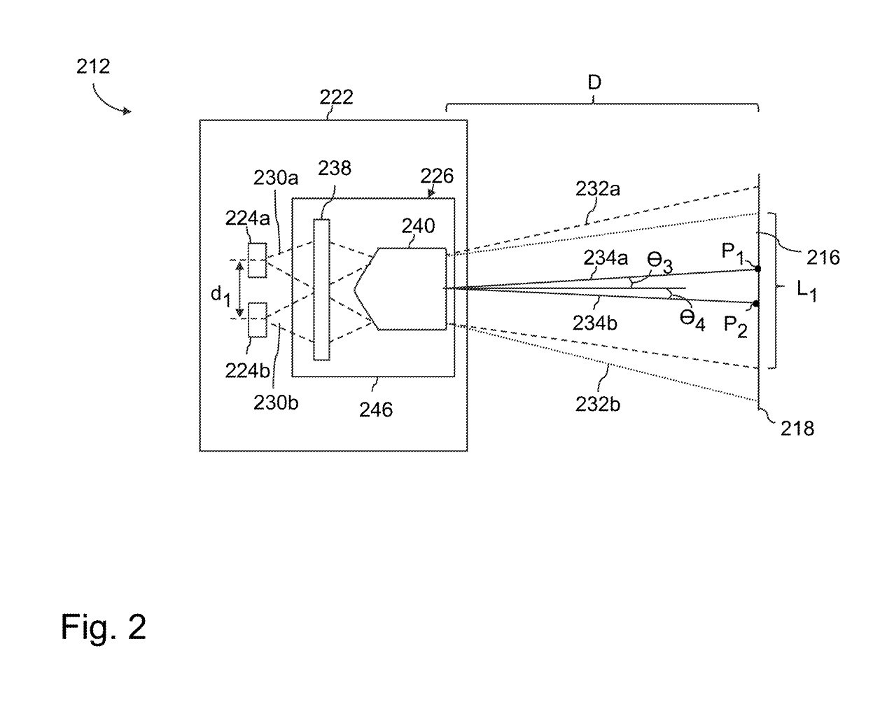

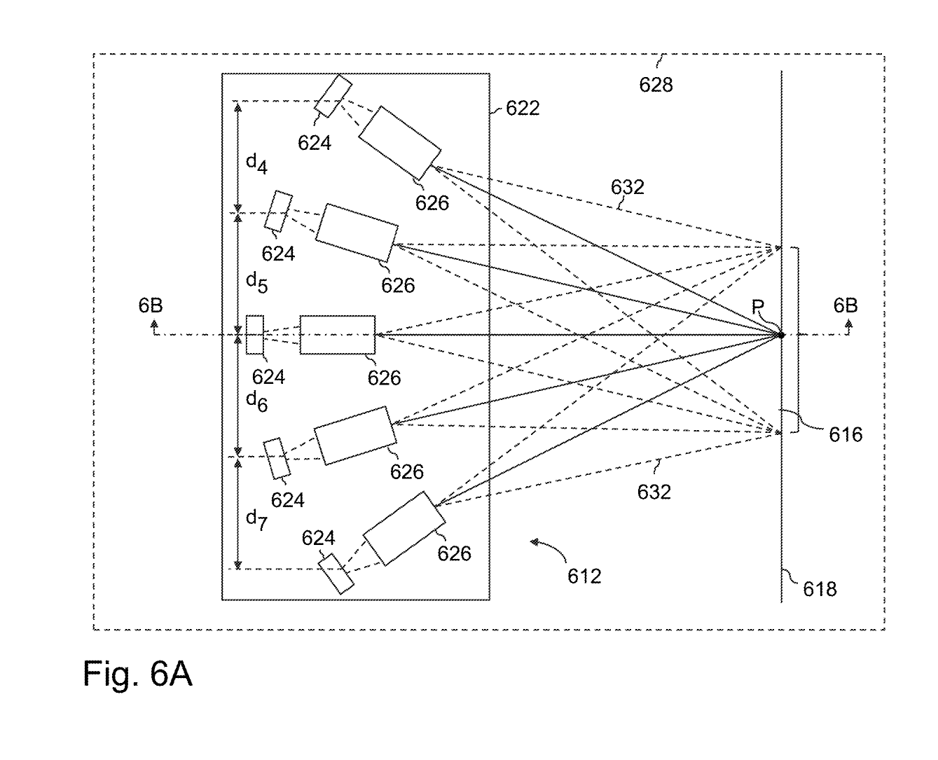

FIG. 2 shows an example of a laser line projector 212, which can reduce speckle, in accordance with an embodiment. As depicted, the laser line projector 212 has two laser sources 224a and 224b secured to the frame 222 and spaced by a spacing distance d₁ from one another. The laser line projector 212 has a working distance D towards which laser line beam paths 232a, 232b are focused. In this example, the laser line projector 212 comprises only one reformatting assembly 226 which, in turn, comprises a single collimating element 238 (e.g. a collimating lens having a focal ranging from 3 to 15 mm, preferably 11 mm) and a single line generating element 240. The laser sources 224a, 224b are oriented towards the collimating element 238 which is used to modify laser beam paths 230a, 230b of the laser sources towards the line generating element 240. During use, the laser beams are collimated and/or focused towards the line generating element 240 such that the laser beams are reformatted into the laser line beams. Further, the collimating element 238 is used to focus the laser beam paths 230a, 230b such that a height h (measured along an axis normal to the projection plane) tapers towards the target (such as seen in FIG. 6B for instance).

The collimating element 238 can be used to collimate, focus, or control the height h of the laser line beam 216 as measured at the target 218. In some embodiments, the collimating element 238 can be a spherical collimating lens which is configured to collimate a laser beam along two in-plane axis (e.g., in the x-axis and in the y-axis). In some other embodiments, the collimating element 238 can also be a cylindrical collimating lens which is configured to collimate a laser beam along a single in-plane axis (e.g., in the x-axis or in the y-axis). It is thus understood that the collimating element 238 can be embodied by one or more spherical collimating lenses, one or more cylindrical collimating lenses, or any combination thereof.

Still referring to FIG. 2, an optical axis 234a of laser line beam path 232a (shown in dashed lines) is not coincident with an optical axis 234b of laser line beam path 232b (shown in dotted lines). Indeed, the optical axis 234a forms an angle θ₃ with respect to a normal of the laser line projector 212 and the optical axis 234b forms an angle θ₄ with respect to the normal of the laser line projector 212, but opposite to the angle θ₃ (θ₃≠θ₄). Still in this embodiment, it can be seen that the optical axis 234a is oriented towards point P₁ and that the optical axis 234b is oriented towards point P₂, which is not coincident with point P₁. Further, it can be seen that composite laser line beam 216 has a length L₁ which corresponds to an overlapping section of the laser line beam paths 232a and 232b projected on target 218.

In other embodiments, such as the ones shown at FIGS. 2-4, the line generating elements 240, 340a, 340b and 440 are acylindrical lenses. The acylindrical lens can be a Powell lens used to tend to achieve composite laser line beams having a substantially uniform intensity profile (i.e. a flat-top profile), for instance. It is understood that the acylindrical lens can also form overcorrected intensity profiles as well as undercorrected intensity profiles. Other types of optical elements having a similar function can be used in alternate embodiments.

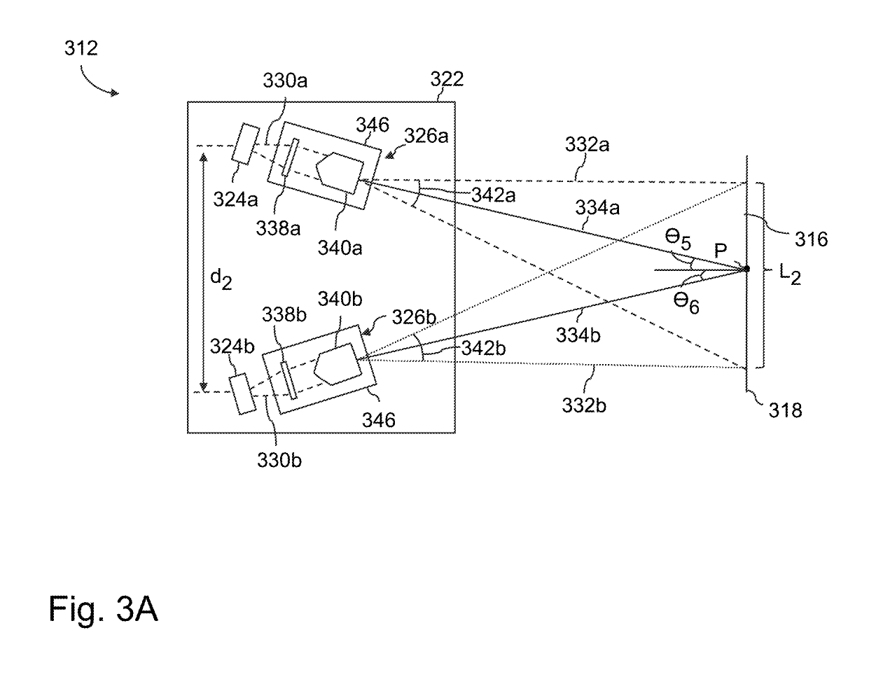

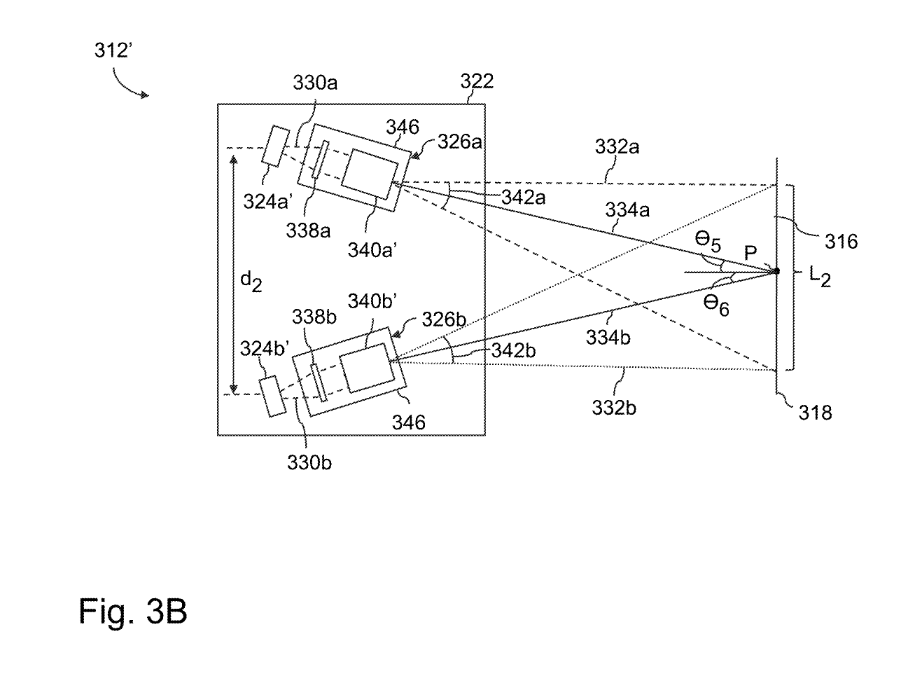

FIG. 3A is another example of a laser line projector 312, which can reduce speckle, in accordance with an embodiment. As depicted, the laser line projector 312 has two laser sources 324a, 324b spaced by a spacing distance d₂ and two reformatting assemblies 326a and 326b. More specifically, each of the laser sources 324a, 324b is optically coupled to a corresponding one of the reformatting assemblies 326a, 326b. Each of the reformatting assemblies 326a, 326b has a corresponding one of collimating element 338a, 338b and line beam generators 340a, 340b. The laser sources 324a, 324b have corresponding laser beam paths 330a, 330b oriented to its corresponding reformatting assembly 326a, 326b such that the collimating elements 338a, 338b and the line beam generators 340a, 340b reformat the laser beam paths 330a, 330b into laser line beam paths 332a, 332b.

In this example, the laser sources 324a, 324b and the reformatting assemblies 326a, 326b are arranged such that the laser line beam paths 332a, 332b are superposed with one another and are oriented towards a common point P of target 318. As depicted, optical axis 334a of the laser line beam path 332a (shown in dashed lines) forms an angle θ₅ relative to a normal of the target 318 while optical axis 334b of the laser line beam path 332b (shown in dotted lines) forms an angle θ₆ relative to the normal of the target 318, wherein θ₅≠θ₆. In this embodiment, the two laser line beam paths 332a, 332b overlap with one another along their entire length such that composite laser line beam 316 has a length L₂.

It is understood that the laser line beam paths 332a, 332b can diverge at fan angles 342a, 342b which can vary depending on the laser sources 324a, 324b and on the reformatting assemblies 326a, 326b (especially the line generating element). Any of the line generating elements 340a, 340b can have a fan angle which ranges between 5° to 75° (preferably 20°).

Further, the laser sources 324a, 324b can emit similar wavelengths. However, in alternate embodiments, the laser source 324a can emit a wavelength which is different from a wavelength emitted by the laser source 324b.

FIG. 3B shows another example of a laser line projector 312′, in accordance with an embodiment. As it can be seen, the laser line projector 312′ is similar to the laser line projector 312 of FIG. 3A. However, in this specific embodiment, the laser sources 324a′, 324b′ include VECSELs. In alternate embodiments, the laser sources 324a′, 324b′ include VECSEL arrays.

Also in this specific embodiment, the line generating elements 340a′, 340b′ are diffusing elements (e.g., diffractive elements, refractive elements). As it will be understood, a line generating element can be embodied by one or more acylindrical lenses (e.g., Powell lens), one or more diffusing elements (e.g., one or more diffractive elements, one or more refractive elements), or any combination thereof.

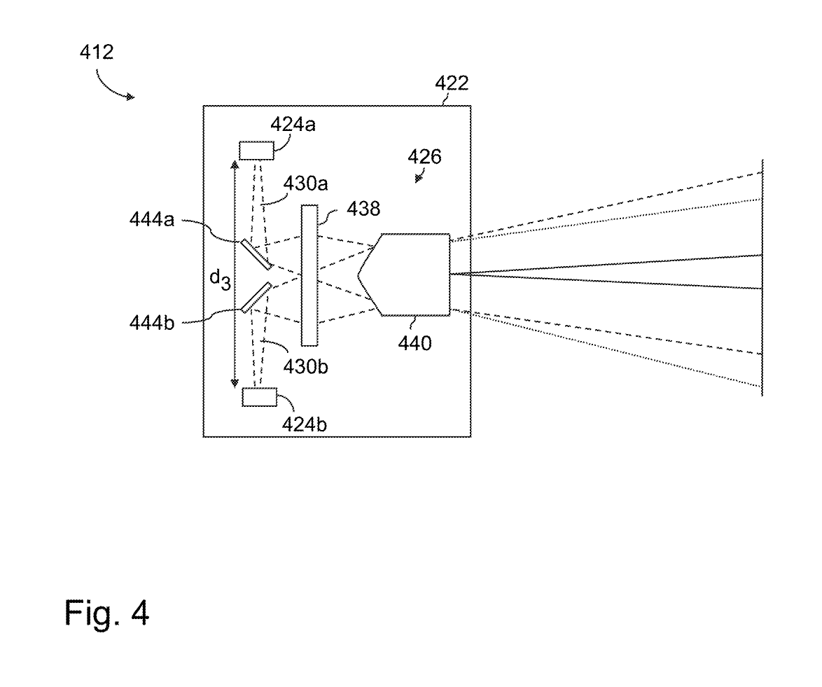

FIG. 4 shows another example of a laser line projector 412, which can reduce speckle, in accordance with another embodiment. As illustrated, the laser line projector 412 has the two laser sources 424a, 424b spaced from a spacing distance d₃ and which are not directly oriented towards the reformatting assembly 426. Indeed, redirecting elements 444a, 444b (e.g. mirrors) are used in order to redirect the laser beam paths 430a, 430b from the laser sources 424a, 424b towards the reformatting assembly 426. Also shown in this embodiment, the collimating element 438 and the line generating element 440 are secured directly to the frame 422 of the laser line projector 412. Reformatting assemblies previously referred to in FIGS. 2-3 are shown to have individual frames 246, 346 of their own, but it is understood that the collimating element 438 and the line generating element 440 can be secured directly to the frame 422 of the laser line projector 412 without such individual frames 246, 346 such as seen in FIG. 4.

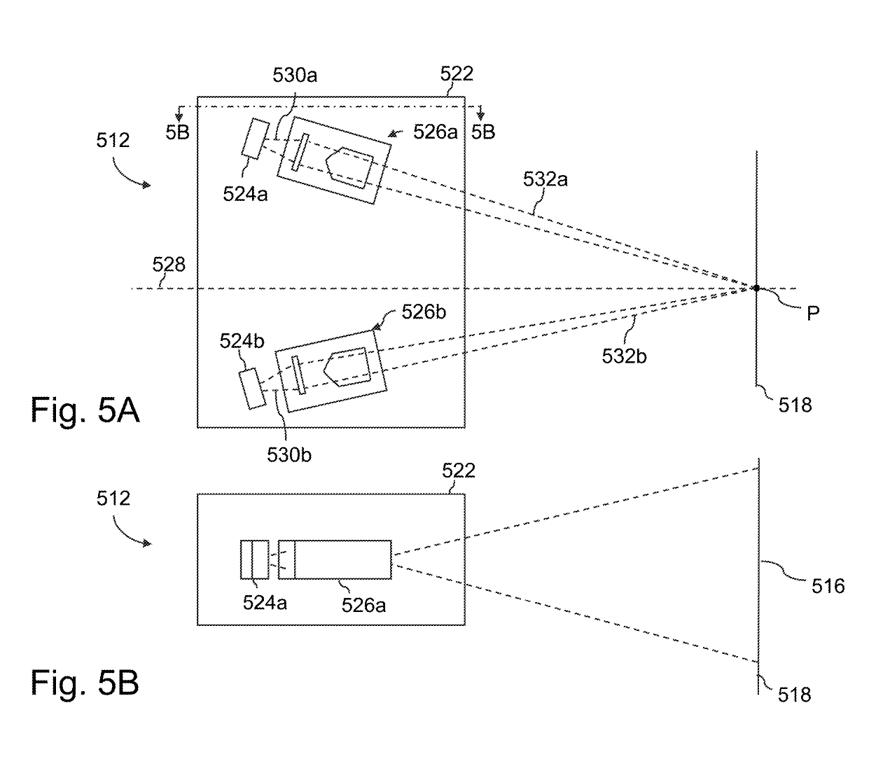

FIGS. 5A-B show another example of a laser line projector 512. More specifically, FIG. 5A is a schematic side view of the laser line projector 512 and FIG. 5B is a cross-sectional view taken along section 5B-5B of FIG. 5A. As shown, the laser sources 524a, 524b and the reformatting assemblies 526a, 526b are arranged to provide laser line beam paths 532a, 532b which are aligned with projection plane 528. The intersection of the laser line beam paths 532a, 532b can be referred to as a laser line beam junction which coincides with the composite laser line beam 516 during use. The laser line beam paths 532a, 532b, which project towards point P of target 518, are thus non-parallel and are superposed at the laser line beam junction to form the composite laser line beam 516. In this specific example, the laser line beam junction and the composite laser line beam are positioned in the projection plane 528. The laser sources 524a, 524b and the laser line beam paths 532a, 532b are not aligned with the projection plane 528 but the laser line beam junction is aligned with the projection plane 528.

FIG. 6A is another example of the laser line projector 612 which shows a cross sectional view cut along a projection plane 628 of the laser line projector 612. In this example, the frame 622 is provided in the form of a housing, as best seen in FIG. 6B. Indeed, FIG. 6B shows a cross-sectional view taken along cross-section 6B-6B of FIG. 6A. As shown, laser sources 624 and reformatting assemblies 626 are secured to the interior of the frame 622 and enclosed therein. The frame 622 has a window 648 through which the laser line beam paths 632 pass. The window 648 can be made of any optically transparent material through which light beams can pass. In another embodiment, an imaging system having a laser line projector and an imaging assembly are secured to the housing via two individual housings each having a respective window through which light beam can pass. In still another embodiment, the window 648 remains empty for convenient access to the optical components secured therein. Still referring to FIG. 6B, it can be seen that the laser line beam paths 632 have a height h which tapers towards the common point P of target 618 due to collimating element 638 of the reformatting assemblies 626. The height h typically tapers down to a laser line height h_{b} when reduced-speckle composite laser line beam 616 illuminates the target 618, as best seen in inset 650.

Referring back to FIG. 6A, the laser line projector 612 has five laser sources 624 and five corresponding reformatting assemblies 626 arranged in a similar manner to the embodiment shown in FIG. 3A. In this embodiment, the laser sources 624 are provided in the form of laser diodes having an emission wavelength typically ranging from 405 to 830 nm, preferably 405 nm, 450 nm, 520 nm, 640 nm, 660 nm or 830 nm or a combination thereof, and a nominal power of 5 mW to 2 W. For instance, a combination of 450 nm, 520 nm and 650 nm laser diodes can be used to generate a pseudo-white color line.

The number of laser sources 624 of the laser line projector 612 is not limited to two or five, it is meant to encompass one or more than one laser sources (e.g. between 2 and 40, preferably between five and fifteen laser sources and reformatting assemblies, most preferably about ten) depending on the circumstances. As shown, the laser sources 624 are spaced from one another by spacing distances d₄, d₅, d₆ and d₇. It is understood that these spacing distances can be similar to one another, but that they can also differ, depending on the configuration of the laser sources 624. In an embodiment, the typical spacing distances vary between 25 and 50 mm, preferably 25 mm.

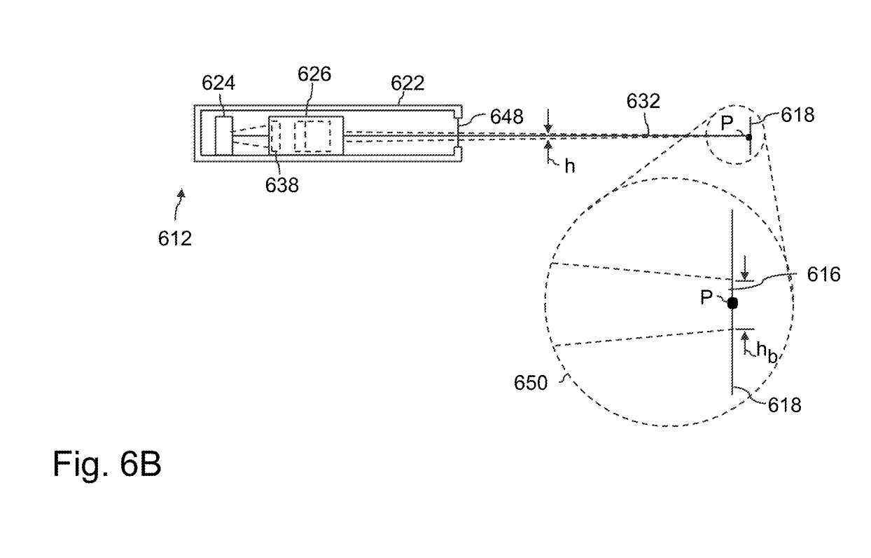

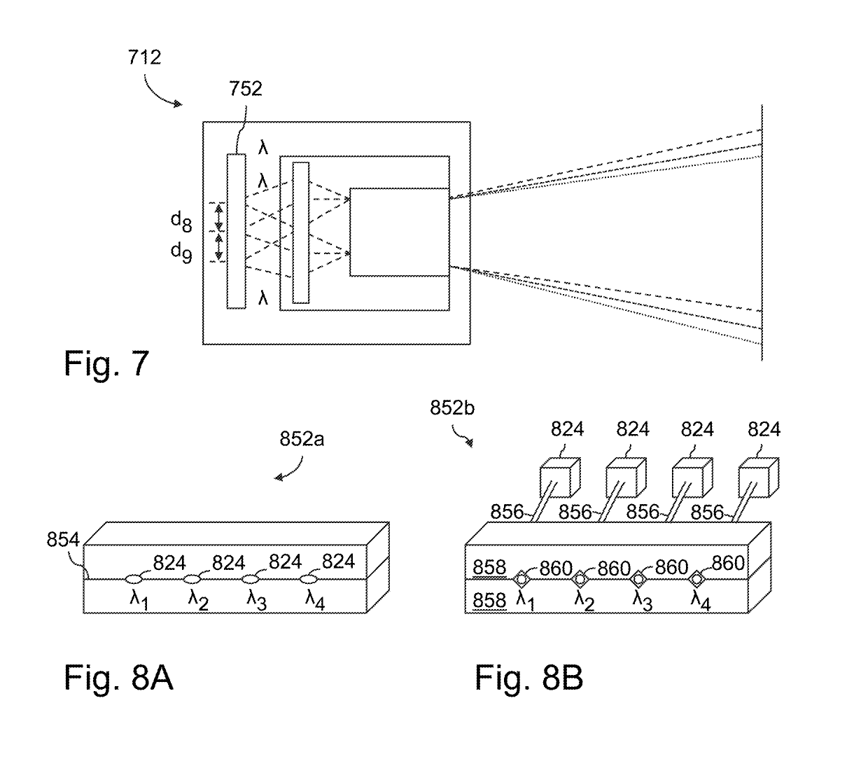

FIG. 7 shows another example of a laser line projector 712, in accordance with an embodiment. As depicted, laser sources of the laser line projector 712 are provided in the form of a single monolithic (i.e. a single piece of glass or crystal) optical device 752 having three optical sources spaced by spacing distances d₈ and d₉. The monolithic optical device 752 thus includes the three laser sources such that three laser beam paths can extend therefrom during use. The monolithic optical device 752 is provided in the form of a single-emitting optical device wherein the three laser beams generated have a similar wavelength λ.

FIGS. 8A-B show examples of monolithic optical devices 852a and 852b, respectively. The monolithic optical devices 852a, 852b are multi-emitting optical devices which are configured to emit different wavelengths, namely λ₁, λ₂, λ₃ and λ₄. Such multi-wavelength emission can also help reduce the speckle of the composite laser line beam. In another embodiment, sources having larger bandwidths Δλ can be used to further help reduce speckling.

More specifically, the monolithic optical device 852a shown in FIG. 8A is a solid-state laser diode which has a plurality of laser sources 824 located at an edge of a junction plane 854 of the monolithic optical device 852a. The laser sources 824 can emit at the same wavelength, or at different wavelengths (λ₁≠λ₂≠λ₃≠λ₄).

Referring now to FIG. 8B, the monolithic optical device 852b is provided in the form of a plurality of optical fibers 856 sandwiched between two V-grooved supports 858. Each of the optical fibers 856 can be connected to different laser sources 824 or to the same laser source via optical couplers (not shown). In the illustrated embodiment, the V-grooved supports 858 form together four grooves 860 each receiving one of the optical fibers 856. Still in this example, the laser sources 824 can emit at the same wavelength, or at different wavelengths (λ₁≠λ₂≠λ₃≠λ₄).

As can be understood, the examples described above and illustrated are intended to be exemplary only. For instance, it is understood that the frame includes alignment systems which can be used in order to align any of the optical components of the laser line projector and/or the imaging assembly. Also, such laser line projectors and imaging systems may comprise polarizers, prisms, optical plates, filters (e.g. to avoid back reflections or crosstalk between the laser beams), and the like. Further, for the sake of clarity and ease of reading, it is understood that a single laser emitter generating a single laser beam then divided into more than one laser beam paths using, for instance, one or more beam splitters, the laser beam paths then being made incoherent such as by modifying their relative lengths by more than the length of coherence, can be used as the plurality of incoherent laser sources fed into the reformatting assembly. The scope is indicated by the appended claims.

What is claimed is:

1. A laser line projector for projecting a composite laser line beam on a target, the laser line projector comprising:
a frame;
a projection plane at a given position relative to the frame;
a plurality of laser sources, being incoherent to one another, secured to the frame, spaced from one another and having a corresponding plurality of laser beam paths; and
a reformatting assembly secured to the frame receiving the plurality of laser beam paths, the reformatting assembly reformatting each of the laser beam paths into one of a plurality of laser line beam paths aligned with the projection plane, the plurality of laser sources and the reformatting assembly being arranged relative to one another such that the plurality of laser line beam paths are projected at different angles towards the target and superposed with one another to form the composite laser line beam during use.

2. The laser line projector of claim 1, wherein the laser line projector is configured such that the composite laser line beam has a substantially uniform intensity profile.

3. The laser line projector of claim 2, wherein the reformatting assembly comprises a line generating element provided in the form of an acylindrical lens.

4. The laser line projector of claim 2, wherein the reformatting assembly comprises a line generating element provided in the form of a diffusing element.

5. The laser line projector of claim 1, further comprising more than one reformatting assemblies such that each reformatting assembly receives one of laser beam paths.

6. The laser line projector of claim 1, wherein the reformatting assembly comprises a collimating element.

7. The laser line projector of claim 1, wherein the reformatting assembly comprises a redirecting element.

8. The laser line projector of claim 1, wherein the frame is provided in the form of a housing enclosing the laser sources and the reformatting assembly, the housing having a window allowing laser line beam paths to pass therethrough.

9. The laser line projector of claim 1, wherein the laser sources are laser diodes.

10. The laser line projector of claim 1, wherein the laser sources include vertical external-cavity surface-emitting lasers (VECSELs).

11. The laser line projector of claim 1, wherein the plurality of laser sources are provided in the form of a multi-wavelength-emitting monolithic optical device.

12. A method for projecting a composite laser line beam on a target, the method comprising the steps of:
providing a plurality of laser beams being incoherent with one another;
reformatting each of the laser beams into one of a plurality of laser line beams; and
projecting, during use, the plurality of laser line beams at different angles towards the target, aligned with a projection plane and superposed with one another to form the composite laser line beam on the target.

13. The method of claim 12, further comprising imaging the composite laser line beam on the target.

14. The method of claim 12, wherein said projecting further comprises selecting each of the angles at which the plurality of laser line beams are projected such that each laser line beams has an optical axis oriented towards a point on the target.

15. An imaging system for imaging a composite laser line beam on a target, the system comprising:
a laser line projector comprising:
a frame;
a projection plane at a given position relative to the frame;
a plurality of laser sources, being incoherent to one another, secured to the frame, spaced from one another and having a corresponding plurality of laser beam paths; and
a reformatting assembly secured to the frame receiving the plurality of laser beam paths, the reformatting assembly reformatting each of the laser beam paths into one of a plurality of laser line beam paths aligned with the projection plane, the plurality of laser sources and the reformatting assembly being arranged relative to one another such that the plurality of laser line beam paths are projected at different angles towards the target and superposed with one another to form the composite laser line beam during use; and
an imaging assembly configured to image the composite laser line beam on the target.

16. The imaging system of claim 15, wherein the imaging assembly is secured to the frame of the laser line projector.

17. The imaging system of claim 15, wherein the frame is provided in the form of a housing enclosing the laser sources and the reformatting assembly, the housing having a window allowing laser line beam paths to pass therethrough.

18. The imaging system of claim 15, further comprising more than one reformatting assemblies such that each reformatting assembly receives one of laser beam paths.

19. The imaging system of claim 15, wherein the plurality of laser sources are provided in the form of a multi-wavelength-emitting monolithic optical device.

20. The imaging system of claim 15, wherein the plurality of laser sources includes vertical external-cavity surface-emitting lasers (VECSELs).
